(19) United States
(12) Patent Application Publication
(10) Pub. No.: US 2013/0148321 A1
(43) Pub. Date: Jun. 13, 2013

(54) EXPANSION SLOT AND MOTHERBOARD HAVING THE EXPANSION SLOT

(71) Applicant: AN-GANG LIANG, Shenzhen City (CN)

(72) Inventor: AN-GANG LIANG, Shenzhen City (CN)

(73) Assignees: HON HAI PRECISION INDUSTRY CO., LTD., Tu-Cheng (TW); HONG FU JIN PRECISION INDUSTRY (ShenZhen) CO. LTD., Shenzhen city (CN)

(21) Appl. No.: 13/340,620

(22) Filed: Dec. 29, 2011

(30) Foreign Application Priority Data
Dec. 8, 2011 (CN) 201110405860.X

(51) Int. Cl. H05K 1/14; H05K 7/00

(52) U.S. Cl. 361/784; 361/679.01

(57) ABSTRACT

An expansion slot used to fix an expansion card includes a main body and two latching members. The main body includes a fixing portion defining a connecting slot for receiving a bottom side of the expansion card, and two clamping portions extending from opposite ends of the fixing portion. The latching members are mounted to the corresponding clamping portions for fixing opposite ends of the expansion card. A groove is defined in a top of one of the latching members.

### BACKGROUND

1. Technical Field

The present disclosure relates to a motherboard with an expansion slot.

2. Description of Related Art

An expansion slot generally includes a main body and two tabs. When an expansion card is mounted to the slot, the tabs respectively abut against opposite ends of the expansion card, to fix the expansion card to the expansion slot. However, when the expansion card is also connected to the motherboard through a cable for receiving a control signal from the motherboard through the cable, the cable may be inadvertently detached from the motherboard or the card when users installs other components on the motherboard. Therefore, there is room for improvement in the art.

### BRIEF DESCRIPTION OF THE DRAWINGS

Many aspects of the embodiments can be better understood with parameter to the following drawings. The components in the drawings are not necessarily drawn to scale, the emphasis instead being placed upon clearly illustrating the principles of the present embodiments. Moreover, in the drawings, like numerals designate corresponding parts throughout the several views.

FIG. 1 is an exploded, isometric view of an expansion slot in accordance with an exemplary embodiment of the present disclosure.

FIG. 2 is an assembled, isometric view of FIG. 1.

FIG. 3 is an assembled, isometric view of a motherboard having the expansion slot of FIG. 1 and an expansion card.

### DETAILED DESCRIPTION

The disclosure, including the drawings, is illustrated by way of example and not by way of limitation. References to “an” or “one” embodiment in this disclosure are not necessarily to the same embodiment, and such references mean at least one.

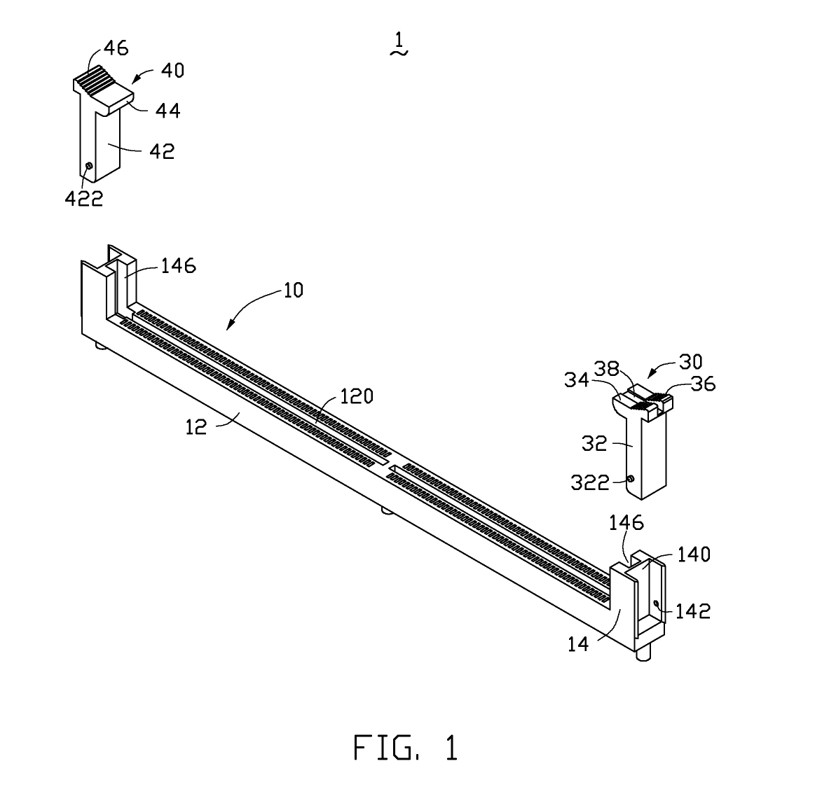

FIG. 1, is an expansion slot 1 in accordance with an exemplary embodiment including a main body 10, and two latching members 30 and 40.

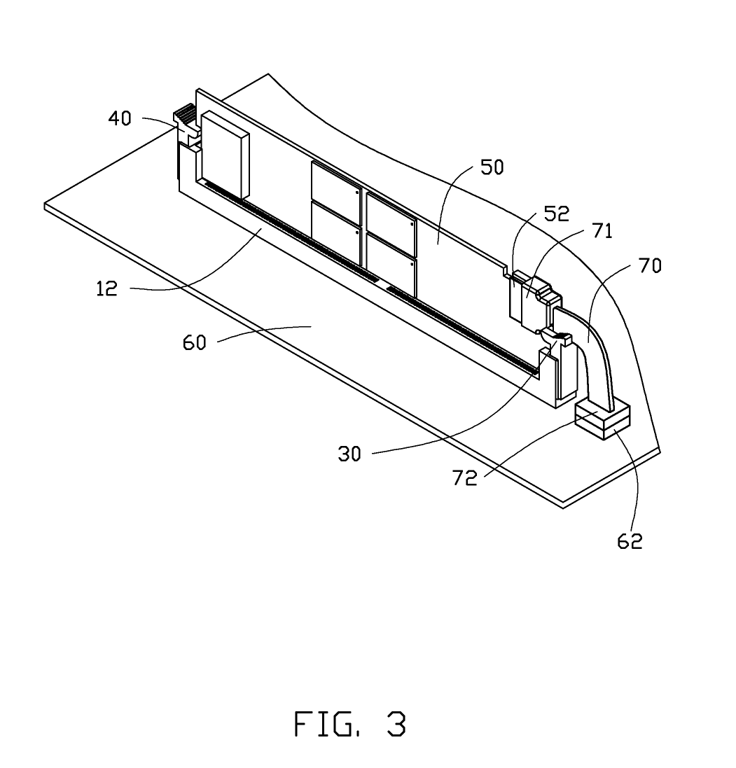

The main body 10 includes a bar-shaped fixing portion 12 and two clamping portions 14 respectively perpendicularly extending up from opposite ends of the fixing portion 12. A top surface of the main body 10 defines a connecting slot 120 for fixing an edge connector of an expansion card 50 at a bottom side (shown in FIG. 3). Each clamping portion 14 defines a receiving slot 146 in an inner side facing the other clamping portion 14 and communication with the connecting slot 120, and a mounting slot 140 in an outer surface opposite to the receiving slot 146. Two opposite sidewalls of each mounting slot 140 each define a pivot hole 142.

The latching member 30 includes a securing portion 32. A block 34 extends from a top of the securing portion 32, and an operation portion 36 extends from the top of the securing portion 32, away from the block 34. Two shafts 322 respectively extend from lower portions of opposite sidewalls of the securing portion 32. A groove 38 is defined in a center of the tops of the block 34 and the operation portion 36, and extends through the block 34 and the operation portion 36, parallel to the connecting slot 120.

The latching member 40 includes a securing portion 42. A block 44 extends from a top of the securing portion 42, and an operation portion 46 extends from the top of the securing portion 42, away from the block 44. Two shafts 422 respectively extend from lower portions of opposite sidewalls of the securing portion 42. In other embodiments, a groove may be defined in a center of the tops of the block 44 and the operation portion 46, extending through the block 44 and the operation portion 46, parallel to the connecting slot 120.

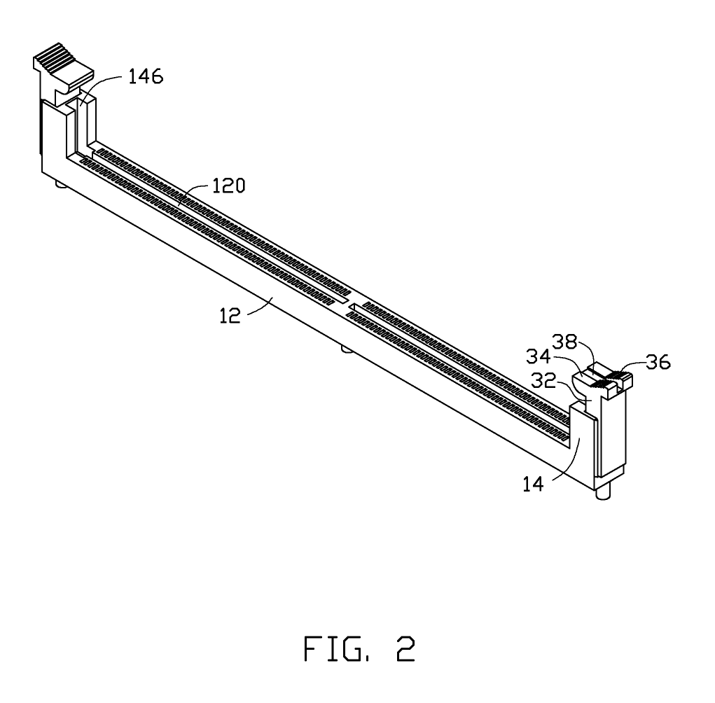

FIGS. 2 and 3, show in assembly, the shafts 322 are engaged in the corresponding pivot holes 142 of a corresponding clamping portion 14, to pivotably mount the latching member 30 to the main body 10. The shafts 422 are engaged in the corresponding pivot holes 142 of the other clamping portion 14, to pivotably mount the latching member 40 to the main body 10. In assembling the expansion card 50, the edge connector of the expansion card 50 is engaged in the connecting slot 120. Opposite ends of the expansion card 50 are respectively received in the receiving slots 146. The operation portions 36 and 46 are pivoted towards the expansion card 50, until the blocks 34 and 44 abut against a top of the expansion card 50. Therefore, the expansion card 50 is fixed to expansion slot 1. A connector 52 arranged on the expansion card 50 is connected to a storage device interface 62 of a motherboard 60 connecting the expansion slot 1 by a cable 70 with two connectors 71 and 72, to receive a control signal from the motherboard 60. The cable 70 is fixed in the groove 38 of the latching member 30, to prevent the cable 70 from loosening.

The expansion slot 1 holds the cable 70, which is connected between the expansion card 50 and the motherboard 60, in the groove 38 of the latching member 30, to prevent the cable 70 from loosening.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An expansion slot for fixing an expansion card, the expansion slot comprising:
a main body comprising a fixing portion defining a connecting slot for receiving a bottom side of the expansion card, and two clamping portions extending up from opposite ends of the fixing portion; and
two latching members mounted to the corresponding clamping portions to fix opposite ends of the expansion card, and one of the latching members defining a groove in a top.

2. The expansion slot of claim 1, wherein each of the latching member comprises a securing portion, two shafts respectively extending from lower portions of opposite sidewalls of the securing portion, each clamping portion defines a mounting slot in an outer surface opposite to the connecting slot, opposite sidewalls of the mounting slot define two holes therein, for rotatably receiving the shafts of the corresponding latching member.

3. The expansion slot of claim 1, wherein a receiving slot configured for receiving a corresponding end of the expansion card is defined in each clamping portion away from the corresponding latching member, an operation portion extends from a top of each latching member away from the receiving slot.

4. The expansion slot of claim 3, wherein a block opposite to the operation portion extends from a top of each latching member for abutting against a top of the expansion card.

5. A motherboard assembly comprising:
a motherboard;
a storage device interface mounted on the motherboard;
an expansion card with a connector;
a cable comprising a first end and a second end, wherein the first end is connected to the connector of the expansion card, the second end is connected to the storage device interface; and
an expansion slot comprising:
a main body comprising a fixing portion defining a connecting slot for receiving a bottom side of the expansion card, and two clamping portions extending up from opposite ends of the fixing portion; and
two latching members mounted to the corresponding clamping portions for fixing opposite ends of the expansion card, one of the latching members defining a groove in a top to receive the cable.

6. The motherboard assembly of claim 5, wherein each of the latching members comprises a securing portion, two shafts respectively extending from lower portions of opposite sidewalls of the securing portion, each clamping portion defines a mounting slot in an outer surface opposite to the connecting slot, opposite sidewalls of the mounting slot define two holes therein, for rotatably receiving the shafts of the securing portion.

7. The motherboard assembly of claim 5, wherein a receiving slot for receiving a corresponding end of the expansion card is defined in each clamping portion facing the connecting slot, an operation portion extends from the top of each latching member away from the receiving slot.

8. The motherboard assembly of claim 7, wherein a block opposite to the operation portion extends from a top of each latching member for abutting against a top of the expansion card.
